(19) United States
(12) Patent Application Publication
(10) Pub. No.: US 2009/0045519 A1
(43) Pub. Date: Feb. 19, 2009

(54) Semiconductor Device and Method of Producing the Same

(76) Inventor: Noritaka Kamikubo, Hiroshima (JP)

Correspondence Address: HARNESS, DICKEY & PIERCE, P.L.C., P.O. BOX 8910, RESTON, VA, 20195, US

(21) Appl. No.: 11/887,946

(22) PCT Filed: Mar. 9, 2006
(86) PCT No.: PCT/JP2006/304622

§ 371 Date: Oct. 5, 2007

(30) Foreign Application Priority Data
Apr. 8, 2005 (JP) 2005-112545

(51) Int. Cl. H01L 21/768; H01L 23/482

(52) U.S. Cl. 257/773; 438/653; 257/E21.584; 257/E23.012

(57) ABSTRACT

In one embodiment of the present invention, a process is disclosed for producing a semiconductor device that can suppress the diffusion of an electrically conductive metal into an insulating film. The process for producing a semiconductor device is characterized by including the steps of (1) forming a groove in an insulating film provided on a semiconductor substrate, (2) forming a barrier film on the inner face of the groove and on the insulating film, (3) forming an electrically conductive metal layer on the barrier film so as to fill the groove, (4) removing the electrically conductive metal layer and barrier film on the insulating film and a part of the electrically conductive metal layer within the groove so that the surface of the electrically conductive metal layer is lower than the surface of the insulating film, (5) forming a metal diffusion preventive film on the insulating film and the electrically conductive metal layer, and (6) removing the metal diffusion preventive film on the insulating film and a part of the insulating film so that at least a part of the metal diffusion preventive film on the electrically conductive metal layer remains unremoved.

### TECHNICAL FIELD

The present invention relates to a semiconductor device and a method of producing the same.

### BACKGROUND ART

In recent years, a buried interconnection technology of a conductive metal, called a damascene process, has been investigated as a technology to obtain higher-density and multi-layered interconnections required along with higher integration of semiconductor integrated circuit devices.

Here, an example of a method of producing the buried interconnection of the conductive metal by the damascene process in conventional methods of producing semiconductor devices will be described by use of FIGS. 7A to 7E. FIGS. 7A to 7E are cross-sectional views showing a production process of this production method.

First, as shown in FIG. 7A, a groove 5 for a buried interconnection is formed by a photolithography technique and a dry etching technique in an insulating film 3 deposited on a semiconductor substrate 1 including semiconductor elements by a CVD (chemical vapor deposition) process or the like.

Next, as shown in FIG. 7B, a barrier film 7 is formed on the inner surface of the groove 5 and on the insulating film 3 by a sputtering method, and further a conductive metal layer 9 made of, for example, copper (Cu) is formed on the barrier film 7 by a plating method so as to fill the groove 5.

Next, as shown in FIG. 7C, an unnecessary conductive metal layer 9 on the barrier film 7 is removed by a CMP (chemical mechanical polishing) method.

Next, as shown in FIG. 7D, a buried interconnection is formed by removing the barrier film 7 on the insulating film 3.

Finally, as shown in FIG. 7E, a metal diffusion preventive film 13 is formed by a plasma CVD process to form a buried interconnection of a conductive metal on the semiconductor substrate.

The damascene process is broadly divided into a single damascene process and a dual damascene process. The single damascene process is a method of forming a buried interconnection as described in FIGS. 7A to 7E. In the dual damascene process, as shown in FIG. 8, the groove 5 for interconnection and a hole 5a for connection to a lower layer interconnection are formed in the insulating film 3, and thereafter the buried interconnection and the hole for connection to the lower layer interconnection are simultaneously formed by the same method as in the single damascene process.

In such a formation method of the buried interconnections, it is necessary to prevent diffusion of the conductive metal into the insulating film from a viewpoint of reliability of a TDDB (time-dependent dielectric breakdown) life span between interconnections, and the like. Particularly in recent years, since copper or the like widely used as a conductive metal material has a relatively large diffusion rate into the insulating film, it is particularly important to certainly prevent the diffusion of the conductive metal into the insulating film 3 by the above barrier film 7 and the metal diffusion preventive film 13.

However, in the above-mentioned conventional method, during removal of the barrier film 7 on the insulating film 3 by the CMP method and during cleaning usually performed after the CMP, the insulating film 3 and the conductive metal layer 9 are simultaneously exposed (refer to FIG. 7D). Therefore, there has been a problem that the conductive metal is diffused into the insulating film 3 by adhesion of a conductive metal scraped off by the CMP method to a surface of the insulating film 3 or contact of an abrasive or a cleaning solution, containing an eluted conductive metal, with the insulating film 3. In addition, a similar problem has arisen also in a step of forming the metal diffusion preventive film 13 after the CMP since the insulating film 3 and the conductive metal layer 9 are simultaneously exposed to plasma at the start of the film formation.

As the methods of countering these problems, for example, a method of cleaning the surface of the insulating film 3 with a cleaning solution including deionized water, an organic acid such as carboxylic acid or ammonium salts thereof, and fluoride compounds or ammonia compounds to remove a conductive metal adhering to the surface in cleaning after the CMP are described in Patent Documents 1 and 2. However, when copper and the like having a large diffusion rate in the insulating film are used as a conductive metal, it is difficult to remove the conductive metal diffused into the insulating film 3 by the methods described in Patent Document 1 or 2. Further, in Patent Document 3, a method of etching and removing the surface of the insulating film 3 into which the conductive metal is diffused after the CMP step is described. Furthermore, in Patent Document 4, a method of using a reducing plasma treatment is described as an etching method.

Patent Document 1: Published Japanese translation of a PCT application 2001-521285

Patent Document 2: Published Japanese translation of a PCT application 2002-506295

Patent Document 3: Japanese Unexamined Patent Publication No. 2001-351918

Patent Document 4: Japanese Unexamined Patent Publication No. 2003-124311

### DISCLOSURE OF THE INVENTION

### Problems to be Solved by the Invention

However, even when these methods are used, the conductive metal is likely to be diffused into the insulating film 3 again in the step of forming the metal diffusion preventive film 13 after the CMP. Therefore, it is difficult to achieve high reliability of the interconnections since the insulating film 3 and the conductive metal layer 9 are simultaneously exposed to plasma at the start of the film formation.

The present invention was made in view of the above state, and it is an object of the present invention to provide a method of producing a semiconductor device which can inhibit the diffusion of a conductive metal into an insulating film.

### Means for Solving the Problems and Effects of the Invention

A method of producing a semiconductor device of the present invention comprises the steps of (1) forming a groove in an insulating film formed on a semiconductor substrate, (2) forming a barrier film on an inner surface of the groove and on the insulating film, (3) forming a conductive metal layer on the barrier film so as to fill the groove, (4) removing the conductive metal layer and the barrier film on the insulating film, and a part of the conductive metal layer in the groove so that the height of the surface of the conductive metal layer becomes lower than that of the surface of the insulating film, (5) forming a metal diffusion preventive film on the insulating film and on the conductive metal layer, and (6) removing the metal diffusion preventive film on the insulating film and a part of the insulating film so that at least a part of the metal diffusion preventive film on the conductive metal layer remains.

In accordance with the present invention, a part of the insulating film can be removed with the conductive metal layer covered with the metal diffusion preventive film. By this removal of the insulating film, the conductive metal diffused into a film surface can be removed, and an insulating film which is free of the diffusion of the conductive metal can be obtained.

Therefore, it becomes possible to prevent deterioration of a TDDB life span between interconnections and form a buried conductive metal interconnection improved in breakdown resistance between interconnections and having high reliability.

### BRIEF DESCRIPTION OF THE DRAWINGS

FIGS. 1A to 1F are cross-sectional views showing a method of producing a semiconductor device according to a first embodiment of the present invention.

FIG. 2 shows a result of analyses of an element concentration profile in a depth direction in a vicinity of an insulating film surface by SIMS, when a third CMP process is not carried out in the first embodiment of the present invention.

FIG. 3 is a cross-sectional view showing a relationship among a difference in level between a surface of a conductive metal layer and the surface of an insulating film, a film thickness of a deposited metal diffusion preventive film, and the removal thickness of an insulating film in the third CMP process in the first embodiment of the present invention.

FIG. 4 is a graph showing a relationship between the difference in level between the surface of the conductive metal layer and the surface of the insulating film and the removal thickness of the insulating film in the third CMP process in the first embodiment of the present invention.

FIGS. 5A to 5F are cross-sectional views showing a method of producing a semiconductor device according to a second embodiment of the present invention.

FIGS. 6A to 6G are cross-sectional views showing a method of producing a semiconductor device according to a third embodiment of the present invention.

FIGS. 7A to 7E are cross-sectional views showing a method of producing a semiconductor device according to a conventional example.

FIG. 8 is a cross-sectional view showing a method of producing a semiconductor device according to a conventional example.

### DESCRIPTION OF THE REFERENCE NUMERALS AND SYMBOLS

1 semiconductor substrate
3 insulating film
3a surface of an insulating film
5 groove for interconnection
7 barrier film
9 conductive metal layer
13 metal diffusion preventive film
15 wafer surface at a stage immediately preceding a third CMP process
17 wafer surface after a third CMP process (polished surface by CMP)
21 copper
31 minimum limit of detection of copper concentration
33 region representing a desirable combination of x and y
x difference in level between the surface of a conductive metal layer and the surface of an insulating film
y film thickness of a deposited metal diffusion preventive film
z removal thickness of an insulating film in a third CMP process
a sum of the removal thickness of a metal diffusion preventive film and the removal thickness of an insulating film in a third CMP process
c film thickness of a residual metal diffusion preventive film in a groove for interconnection in a third CMP process

### BEST MODE FOR CARRYING OUT THE INVENTION

A method of producing a semiconductor device of the present invention comprises the steps of (1) forming a groove in an insulating film formed on a semiconductor substrate, (2) forming a barrier film on the inner surface of the groove and on the insulating film, (3) forming a conductive metal layer on the barrier film so as to fill the groove, (4) removing the conductive metal layer and the barrier film on the insulating film, and a part of the conductive metal layer in the groove so that the height of the surface of the conductive metal layer becomes lower than that of the surface of the insulating film, (5) forming a metal diffusion preventive film on the insulating film and on the conductive metal layer, and (6) removing the metal diffusion preventive film on the insulating film and a part of the insulating film so that at least a part of the metal diffusion preventive film on the conductive metal layer remains.

Removal of the conductive metal layer and the barrier film in the step (4) can be performed by various methods, and it can be performed, for example, by a CMP method or a combination of the CMP method and an etching method.

Specifically, the step (4) can be performed, for example, by a method comprising the steps of removing the conductive metal layer on the insulating film, and removing the barrier film on the insulating film and a part of the conductive metal layer in the groove (corresponding to the following first embodiment). The step (4) may also be performed by a method comprising the steps of removing the conductive metal layer on the insulating film and a part of the conductive metal layer in the groove, and removing the barrier film on the insulating film (corresponding to the following second embodiment). In the former method, in removing the barrier film, difference in level between the surface of the conductive metal layer and the surface of the insulating film (hereinafter, also referred to as just “difference in level”) is formed, and in the latter method, in removing the conductive metal layer on the insulating film, the difference in level is formed. Both methods can be performed, for example, by repeating a CMP process twice. This twice-repeated CMP process can be continuously performed by changing species of slurry, or the like.

Further, the step (4) may be a method comprising the steps of removing the conductive metal layer and the barrier film on the insulating film by a CMP method, and removing a part of the conductive metal layer in the groove by etching (for example, wet etching) (corresponding to the following third embodiment). In this method, the height of the difference in level is easily controlled since the difference in level is formed by etching after the surface is planarized once by the CMP method.

In the step (4), the difference in level between the surface of the conductive metal layer and the surface of the insulating film is preferably set at 70 to 500 nm. The reason for this is that when the difference in level is 70 nm or more, it is possible to leave the metal diffusion preventive film of 20 nm or more in thickness on the conductive metal layer while removing the insulating film by 50 nm or more in the step (6), and when the difference in level is 500 nm or less, the groove for burying a conductive metal does not become too deep. Further, the reason for removing the insulating film by 50 nm or more is that since most of the diffusion of the conductive metal occurs in a region up to 50 nm in depth, most of the diffused conductive metal can be removed by removing the insulating film by 50 nm or more. Further, the reason for leaving the metal diffusion preventive film of 20 nm or more in thickness is that the metal diffusion preventive film of 20 nm or more in thickness exert an adequate function of preventing the diffusion.

It is preferable that the above-mentioned difference in level is formed so as to be smaller than the value obtained by subtracting 40 nm from the double value of the film thickness of the metal diffusion preventive film. The reason for this is that in this case, the difference in level is relatively small relative to the film thickness of the deposited metal diffusion preventive film, and therefore planarization becomes easy.

In the step (5), it is preferable to form the metal diffusion preventive film having a film thickness of 20 to 500 nm. The reason for this is that in this case, it is possible to retain the film of 20 nm or more till after the step (6), and in the film of 500 nm or less, it does not take too much time and cost to form the film.

In the step (6), it is preferable to remove the insulating film by 50 to 500 nm. The reason for removing the film by 50 nm or more is as described above. The reason for removing by 500 nm or less is that a film thickness to be formed excessively in thickness in advance does not become too thick. Further, it is preferable to leave the metal diffusion preventive film of 20 to 500 nm in thickness on the conductive metal layer. The reason for leaving the metal diffusion preventive film of 20 nm or more is as described above. The reason for leaving the film of 500 nm or less is that it does not take too much time and cost to form the film.

In addition, the difference in level formed in the step (4) is preferably larger than the removal thickness of the insulating film by 20 to 500 nm. The reason for this is that in this case, the metal diffusion preventive film having a film thickness of 20 to 500 nm is formed, and it is possible to retain this film till after the step (6) with almost no reduction in the film thickness.

Further, the present invention provides a semiconductor device, comprising a semiconductor substrate, an insulating film with a groove, formed on the substrate, a conductive metal layer filled into the groove with a barrier film therebetween, and a metal diffusion preventive film formed so as to cover the conductive metal layer, wherein the surface of the insulating film and the surface of the metal diffusion preventive film are substantially in the same plane. This semiconductor device can be produced by the above-mentioned method, can reduce an amount of conductive metal contained in the insulating film, and can prevent the deterioration of a TDDB life span between interconnections.

Hereinafter, the embodiments of the present invention will be described by use of cross-sectional views of the respective steps. Shapes, structures, film thickness, temperatures, composition or methods, shown in drawings and the following descriptions, are exemplifications, and the scope of the present invention is not limited to those shown in drawings and the following descriptions.

### 1. FIRST EMBODIMENT

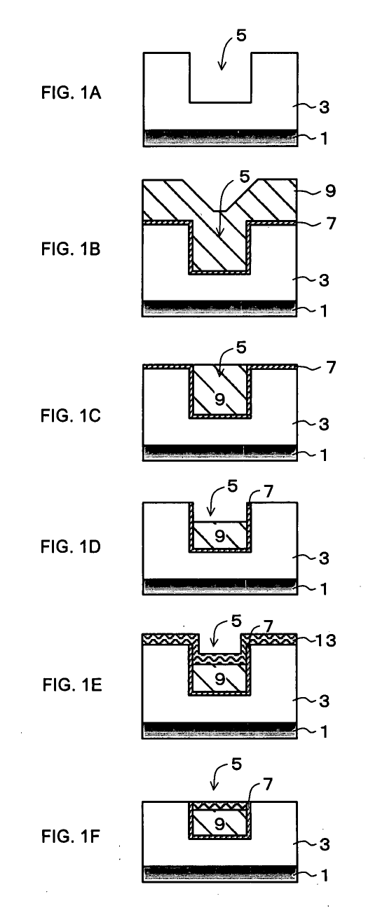

FIGS. 1A to 1F are cross-sectional views for illustrating a method of producing a semiconductor device according to the first embodiment of the present invention.

### 1-1. Description of Method of Producing Semiconductor Device

### (1) Step of Forming Groove

First, as shown in FIG. 1A, a groove 5 for a buried interconnection is formed by a photolithography technique and a dry etching technique in an insulating film 3 with a thickness of 100 to 2000 nm provided on a semiconductor substrate 1 including semiconductor elements.

The insulating film 3 is an insulating film between interconnections, and for example, a silicon dioxide film, a low-k film, and the like can be employed. As the low-k film, inorganic insulating films such as a SiOF film, a SiOC film, a porous silica film and the like, and organic insulating films such as a polyimide film, a fluorine-doped amorphous carbon film and the like can be employed.

The photolithography technique and the dry etching technique can be carried out by a normal method, and they can be carried out, for example, by the following methods: (a) A photoresist composition is applied onto the insulating film 3 to form a photoresist layer; (b) A resist pattern is formed by exposing and developing the photoresist layer at optimal light exposure and focus using an ArF excimer laser scanner; and (c) A groove 5 is formed by using the resist pattern as a mask, and dry-etching the insulating film 3. A chemically amplified positive photoresist composition including a usual base resin, an acid generator, and the like, can be used for the photoresist composition. The dry etching technique can be carried out by use of etching gases such as CₓF_{y}, CₓH_{y}F_{z}, O₂, N₂, and Ar.

Thus, the groove 5 is formed so as to be connected to a desired location of a semiconductor element located on the semiconductor substrate 1, or a lower layer interconnection or a connecting electrode connected to this semiconductor element.

In addition, the film thickness, the composition, and the forming procedure of the insulating film 3, and the shape and the forming procedure of the groove 5 are not limited to those described above. The insulating film 3 or the groove 5 may be one which is suitable for forming buried conductive metal interconnections or connecting electrodes.

### (2) Step of Forming Barrier Film

Next, as shown in FIG. 1B, a barrier film 7 with a thickness of 1 to 50 nm is formed on the inner surface of the groove 5 and on the insulating film 3 by a sputtering method or the like. Here, for the barrier film 7, (a) heat resistant metals such as titanium, tantalum or tungsten, (b) nitrides of the heat resistant metals such as titanium nitride, tantalum nitride or tungsten nitride, (c) ruthenium or ruthenium oxide, or (d) a laminated film of thin films made of the materials (a) to (c) can be used.

In addition, the constitution (a single-layered film or a laminated film), the film thickness, the composition, and the forming procedure of the barrier film 7 are not limited to those described above. The barrier film 7 may be a film having a function of preventing the conductive metal filled into the groove 5 in the subsequent step from diffusing into the insulating film 3.

### (3) Step of Forming Conductive Metal Layer

Next, a conductive metal layer 9 is formed on the barrier film 7. In this step, the conductive metal layer 9 is deposited so as to fill at least the groove 5. The conductive metal layer 9 is more desirably deposited so as to have a film thickness 1.1 to 2 times as long as the depth of the groove 5 so that a high planarizing property is attained in a first CMP process described later. The conductive metal layer 9 can be formed using a metal of low resistivity such as gold, silver or platinum, or an alloy containing these metals besides copper from the viewpoint of making interconnections lower in resistivity.

The conductive metal layer 9 can be formed, for example, by the following procedures: (a) A seed film, made of copper, with a thickness of about 50 to 150 nm is formed on the barrier film 7 by a sputtering method or a CVD method; (b) A plated film made of copper is formed on the seed film by an electrolytic plating method (current density: about 3 to 50 mA/cm²) using a plating solution having copper sulfate as the main component to obtain the above-mentioned thickness; and (c) Then, the resulting film is annealed at a temperature of 150° C. to 350° C. in an inert atmosphere.

By the steps described above, a conductive metal layer 9 of good film quality can be obtained.

In addition, the constitution (a single-layered film or a laminated film), the film thickness, the composition, and the forming procedure of the conductive metal layer 9 are not limited to those described above. The conductive metal layer 9 may be one capable of being buried in the groove 5.

### (4) Step of Removing a Part of Conductive Metal Layer

Next, as shown in FIG. 1C, an unnecessary conductive metal layer 9 on the barrier film 7 is removed by a first CMP. This CMP can be carried out by use of an abrasive (slurry) including an abrasive grain of silica (silicon dioxide), alumina (aluminum oxide) or ceria (cerium oxide), and an oxidizer such as hydrogen peroxide solution.

This CMP can be carried out, for example, under the conditions: an abrasive: an abrasive including an aluminum oxide abrasive grain and 2.5% by weight hydrogen peroxide solution known as a common abrasive for Cu-CMP; an abrasive flow rate: 200 ml/min; polishing pressure: 21 kPa; the number of revolutions of a surface plate: 90 rpm; and the number of revolutions of a wafer: 85 rpm. In this time, a polishing rate of the conductive metal layer 9 made of copper becomes 600 nm/min. This CMP is carried out until the barrier film 7 is exposed. By changing the conditions of the CMP to those of the polishing pressure: 14 kPa, the number of revolutions of a surface plate: 45 rpm, and the number of revolutions of a wafer: 43 rpm immediately before the barrier film 7 is exposed to reduce the copper-polishing rate to 200 nm/min or less, flatness can be improved.

Next, as shown in FIG. 1D, the barrier film 7 on the insulating film 3 is removed by second CMP. At this time, the height of the surface of the conductive metal layer 9 in the groove 5 is made lower than that of the surface of the insulating film 3. This CMP can be carried out by use of an abrasive including an abrasive grain of silica (silicon dioxide), alumina (aluminum oxide) or ceria (cerium oxide), and an oxidizer of a conductive metal and an ingredient to etch an oxidized film of a conductive metal.

This CMP can be carried out, for example, under the conditions: an abrasive: an abrasive including a silica abrasive grain, hydrogen peroxide solution and organic acid (citric acid, etc.); an abrasive flow rate: 200 ml/min; a polishing pressure: 21 kPa; the number of revolutions of a surface plate: 100 rpm; and the number of revolutions of a wafer: 93 rpm. In this time, a polishing rate of the conductive metal layer 9 made of copper becomes 100 nm/min, a polishing rate of the barrier film 7 made of tantalum and tantalum nitride films becomes 100 nm/min, and a polishing rate of the insulating film 3 becomes 10 nm/min or less. This CMP is terminated after performing over-polishing for 30 seconds or more after the insulating film 3 is exposed. Thereby, it is possible to make the height of the surface of the conductive metal layer 9 within the groove 5 lower than that of the surface of the insulating film 3.

Other abrasives may be used in place of the above-mentioned abrasives if they have polishing selectivity with regards to the insulating film 3, that is, they are abrasives by which a polishing rate of the insulating film 3 is relatively low.

Further, it is desirable to remove the insulating film 3 by 5 to 200 nm so that the barrier film 7 may not remain in small bumps and dips on the surface of the insulating film 3. Thereby, it is possible to prevent the barrier film 7 from remaining and secure an insulating property between interconnections.

Removal of the insulating film 3 can be carried out by CMP of, for example, the conditions: an abrasive: an abrasive including a silica abrasive grain; a polishing pressure: 21 kPa; the number of revolutions of a surface plate: 100 rpm; and the number of revolutions of a wafer: 93 rpm. In this time, a polishing rate of the conductive metal layer 9 made of copper becomes 100 nm/min, a polishing rate of the barrier film 7 made of tantalum and a tantalum nitride film becomes 100 nm/min, and a polishing rate of the insulating film 3 becomes 100 nm/min.

By performing the CMP under these conditions to remove the insulating film 3 by 5 to 200 nm, and then performing the above second CMP, it is possible to prevent the barrier film 7 from remaining.

After the second CMP process, the steps of performing an anti-corrosive treatment of the surface of the conductive metal layer 9 and of cleaning and drying the polished surface are performed. These steps can be performed, for example, according to the following methods. (a) A protective film is formed on a copper surface with a chemical including an anticorrosive such as 0.01 to 1% by weight BTA (benzotriazole) to protect copper from advancing oxidation. (b) Next, the surface is cleaned with a common post cleaner of polishing, which contains organic acid such as about 1% oxalic acid and a surfactant to remove adequately an abrasive or the like adhering to the surface. (c) Next, the polished surface is rinsed with pure water. (d) Next, the wafer is rotated at 1000 rpm or more to dry the surface.

The above-mentioned conditions of the second CMP are not limited to those described above. Further, a method of removing a part of the conductive metal layer 9 is not limited to the second CMP and another method may be employed.

### (5) Step of Forming Metal Diffusion Preventive Film

Next, as shown in FIG. 1E, a metal diffusion preventive film 13 is formed on the insulating film 3 and the conductive metal layer 9. The metal diffusion preventive film 13 is a film for preventing the conductive metal from diffusing into other films, and the metal diffusion preventive film 13a is, for example, formed of a material such as SiN, SiC, SiON, SiCN, or the like with a thickness of 20 to 200 nm by the CVD method.

In addition, the constitution (a single-layered film or a laminated film), the film thickness, the composition, and the forming procedure of the metal diffusion preventive film 13 are not limited to those described above.

### (6) Step of Removing a Part of Metal Diffusion Preventive Film

Finally, as shown in FIG. 1F, by the third CMP, at least a part of the metal diffusion preventive film 13 formed on the conductive metal layer 9 is left, and all of the metal diffusion preventive film 13 formed on the insulating film 3 and a part of the insulating film 3 are removed to form a buried interconnection of conductive metal on a semiconductor substrate.

This CMP can be carried out, for example, by use of an abrasive including an abrasive grain of silica (silicon dioxide), alumina (aluminum oxide), ceria (cerium oxide), or the like. More specifically, this CMP can be carried out, for example, under the conditions: an abrasive: an abrasive including a silicon dioxide abrasive grain; an abrasive flow rate: 200 ml/min; a polishing pressure: 21 kPa; the number of revolutions of a surface plate: 100 rpm; and the number of revolutions of a wafer: 93 rpm. In this time, a polishing rate of the metal diffusion preventive film 13 made of SiN becomes 80 nm/min, and a polishing rate of the insulating film 3 becomes 100 nm/min. The insulating film 3 is preferably removed by 50 nm by this CMP.

In this CMP, it is not necessary to use abrasives which are different in polishing rate of the metal diffusion preventive film 13 and of the insulating film 3. In this CMP, the metal diffusion preventive film 13 and the insulating film 3 may be simultaneously polished to planarize the surface using a common abrasive.

In this third CMP, it is important to leave at least a part of the metal diffusion preventive film 13 formed on the conductive metal layer 9. In a process from the previously described second CMP step to the step of forming a metal diffusion preventive film, the conductive metal is diffused into the vicinity of the surface of the insulating film 3 due to the same reason as that described in the paragraph of Problems to be Solved by the Invention. But, by performing the third CMP with the conductive metal layer 9 covered with the metal diffusion preventive film 13, a region (the surface layer of the insulating film 3) into which the conductive metal is diffused can be removed.

In the subsequent cleaning step after the CMP and the step of forming an upper insulating film, since the conductive metal layer 9 is similarly covered with the metal diffusion preventive film 13, the conductive metal is not diffused again into the vicinity of the surface of the insulating film 3. Thereby, it is possible to prevent the breakdown of the surface of the insulating film 3 resulting from a metal-contaminated layer and improve the reliability of interconnections.

The above-mentioned conditions of the CMP are not limited to those described above. A method of removing a part of the metal diffusion preventive film 13 is not limited to the CMP and another method may be employed.

### 1-2. Results of SIMS Analysis

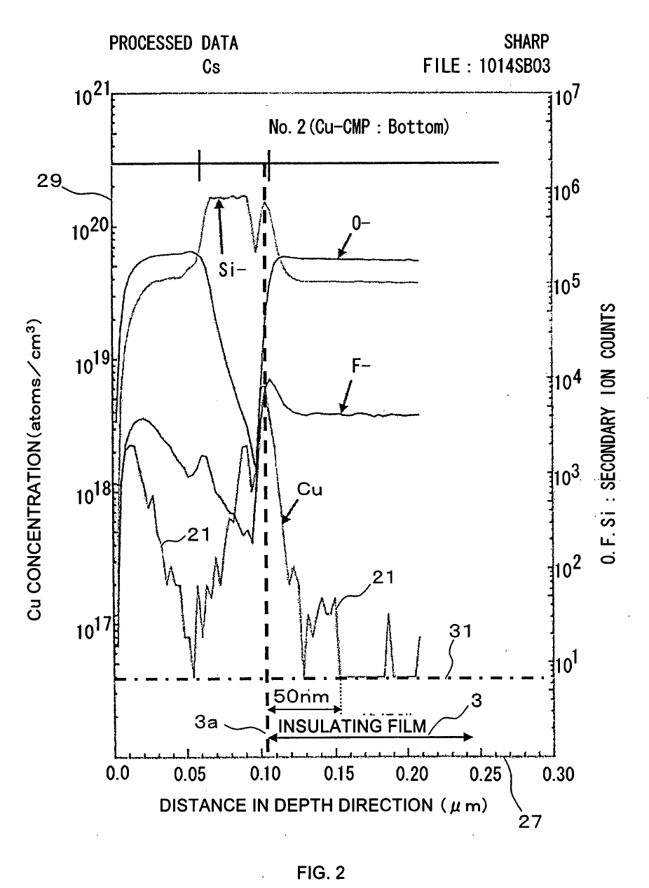

FIG. 2 shows a result of analyses of an element concentration profile in the depth direction in a vicinity of the surface of the insulating film 3 by SIMS process (secondary ionization mass spectrometer), when the third CMP process is not carried out. As for samples for analysis, a sample including the insulating film 3 made of silicon oxide, the conductive metal layer 9 made of copper, and the metal diffusion preventive film 13 made of SiN is used. The analysis is performed under conditions in which species of a primary ion is Cs+ (acceleration energy: 14.5 keV) and a beam current is 20 nA. A horizontal axis 27 of FIG. 2 represents a distance in the depth direction and a vertical axis 29 represents a concentration of each element, and the cooper concentrations 21 in the vicinity of the surface 3a of the insulating film 3 are shown in FIG. 2. Here, a minimum limit of detection of copper concentration 31 is about 5×10¹⁶ atoms/cm³.

As is evident from this result, when the third CMP process was not carried out, in the vicinity of the surface 3a of the insulating film 3, copper of the order of up to 7×10¹⁸ atoms/cm³ is diffused over the region of about 50 nm in depth, and in a deeper region, a copper concentration is almost below a minimum limit of detection 31. Therefore, in the third CMP, by removing a region from the surface of the insulating film 3 up to 50 nm or more in depth, most of the region into which the conductive metal is diffused can be removed, and therefore more preferable result can be achieved.

Further, an upper limit of a removal thickness of the insulating film 3 in the third CMP is not particularly limited, but since an insulating film have to be deposited to have the ultimately desired thickness of the insulating film 3 plus this removal thickness in the third CMP in advance, the removal thickness is preferably in a range in which the thickness of the insulating film does not cause the difficulty in forming the groove 5. This upper limit of the removal thickness is determined by a minimum line width of the groove 5, and it is desirably set at about 500 nm or smaller which is an interconnection height used in normal interconnection formation.

Further, in the second CMP process, it is preferable to adapt the film so that the height of the surface of the conductive metal layer 9 in the groove 5 is lower than that of the surface of the insulating film 3 by 70 nm or more, and it is preferable to form the metal diffusion preventive film 13 of 20 nm or more in thickness. The reason for this is that in this case, when the region from the surface of the insulating film 3 up to 50 nm in depth is removed in the third CMP, it becomes possible to leave the metal diffusion preventive film 13 of 20 nm or more in thickness on the conductive metal layer 9. Thereby, since an adequate effect of preventing the diffusion into the conductive metal layer 9 can be achieved, it is not necessary to laminate another metal diffusion preventive film newly in a subsequent step and the number of processes and volume between the interconnections are respectively reduced, and therefore it is more preferable.

### 1-3. Relationship Among Difference in Level Between Surfaces, Film Thickness of Deposited Metal Diffusion Preventive Film, and Removal Thickness of Insulating Film

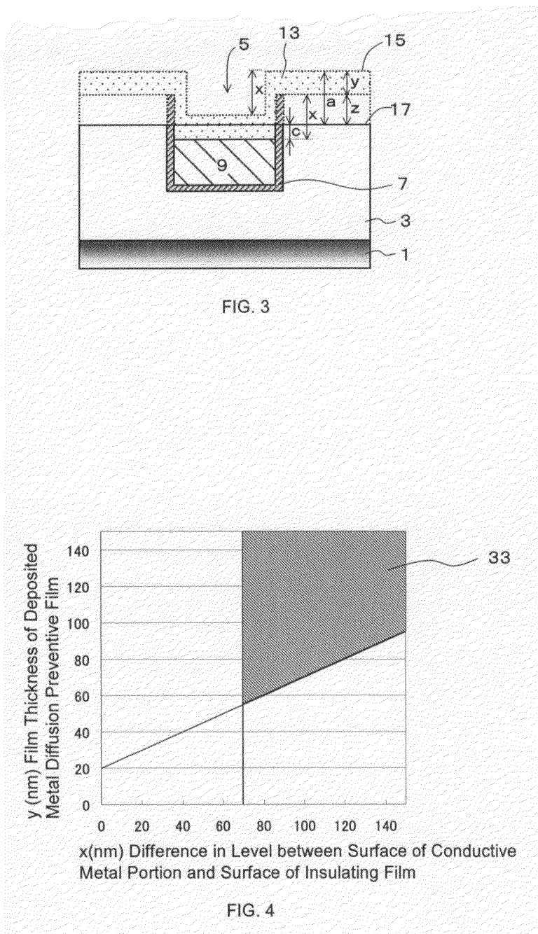

FIG. 3 is a cross-sectional view for showing a relationship among the difference in level, formed in the second CMP process, between the surface of the conductive metal layer 9 in the groove 5 and the surface of the above insulating film 3, the film thickness of the deposited metal diffusion preventive film 13, and the removal thickness of the insulating film 3 in the third CMP process. In this figure, a symbol 15 represents a wafer surface at the stage immediately preceding the third CMP process, and a symbol 17 represents a wafer surface at the stage after the third CMP process (the so-called polished surface by CMP). Further, in FIG. 3, all units of x, y, z, a, and c are nanometer (nm), and the respective symbols have the following meanings.

x (nm): the difference in level, formed in the second CMP process, between the surface of the conductive metal layer 9 in the groove 5 and the surface of the above insulating film 3

y (nm): the film thickness of the deposited metal diffusion preventive film 13

z (nm): the removal thickness of the insulating film 3 in the third CMP process

a (nm): the sum of the removal thickness of the metal diffusion preventive film 13 and the removal thickness of the insulating film 3 in the third CMP process

c (nm): the film thickness of the residual metal diffusion preventive film 13 remaining after the third CMP process

It is found from FIG. 3 that c=x−z and therefore a relationship of c>20 (nm) holds always when x>z+20 (nm) and y>20 (nm).

Therefore, even when the required removal thickness z of the film varies, the film thickness c of the residual metal diffusion preventive film 13 can be maintained at a thickness of 20 nm or more, by forming the difference x in level between the surfaces so as to be larger than the removal thickness z of the metal diffusion preventive film 13 by 20 nm or more and depositing metal diffusion preventive film 13 so as to have a film thickness y of 20 nm or more.

Further, the difference in level on the wafer surface 15 at the stage immediately preceding the third CMP process (i.e., the difference in level on the surface of the insulating film 3) depends on the shape of pattern (namely a width of the groove 5) in an interconnection portion composed of the conductive metal layer 9. This difference in level on the wafer surface 15 decreases as the width of the groove 5 decreases, and it reaches an upper limit and becomes almost constant when the width of the groove 5 is above a certain level. This upper limit of the difference in level is approximately equal to x as shown in FIG. 3.

When the sum of the removal thicknesses a (nm) of the films in the third CMP process is about 1.5 times or more an initial difference in level x (nm) at this CMP process, the initial difference in level x (nm) is easily resolved in this CMP process. Such the CMP process is desirable from the viewpoint of process margin and cost. Therefore, it is preferable to satisfy the following inequality:

a>1.5×x (nm) (1).

Further, since from FIG. 3, a=y+z (nm), in order to make z (the removal thickness (nm) of the insulating film 3 in the third CMP process) 50 nm or more, it is only necessary to satisfy the following inequality:

a>y+50 (nm) (2).

Furthermore, since c (the film thickness of a residual metal diffusion preventive film 13 remaining after the third CMP process) is desirably 20 nm or more, it is desirable that c>20 (nm), and since from FIG. 3, a+c=y+x, that is, c=y+x−a, it is only necessary to satisfy the following inequality:

y+x−20>a (nm) (3).

Solving simultaneous equations of the above-mentioned equations (1), (2), and (3),

x>70 (nm) and x<2y−40 (nm).

A region denoted by a reference numeral 33 in FIG. 4 represents a combination of x and y, satisfying the above two equations. As is readily understood from this drawing, there are solutions only when y>55 (nm).

From the above description, it is evident that preferably, the difference in level, formed in the second CMP process, between the surface of the conductive metal layer 9 in the groove 5 and the surface of the above insulating film 3 is larger than 70 nm and smaller than the value obtained by subtracting 40 nm from the doubled value of the film thickness of the deposited metal diffusion preventive film 13. In this case, there are advantages that a) a process margin of the third CMP process is large, (b) the removal thickness of the insulating film 3 can be 50 nm or more, and (c) the film thickness of the residual metal diffusion preventive film 13 can be 20 nm or more.

Further, the first and the second CMP processes can be continuously performed by changing abrasives. In this case, the number of production process steps of the semiconductor device can be reduced.

### 2. SECOND EMBODIMENT

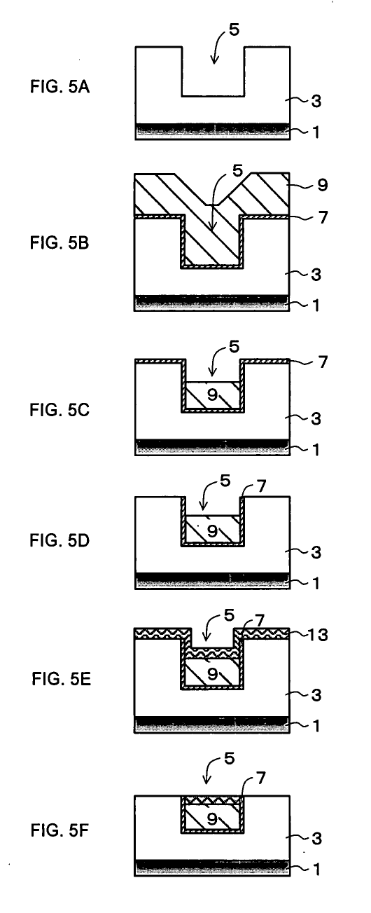

FIGS. 5A to 5F are cross-sectional views for illustrating a method of producing a semiconductor device according to the second embodiment of the present invention. In this embodiment, the constitution and the forming procedure of the semiconductor device in the steps up to forming of the conductive metal layer 9 shown in FIGS. 5A and 5B and in the steps from forming of the metal diffusion preventive film 13 shown in FIGS. 5E and 5F on are the same as those of First Embodiment.

As shown in FIG. 5C, the conductive metal layer 9 on the barrier film 7 and a part of the conductive metal layer 9 in the groove 5 are removed by the first CMP to make the height of the surface of the conductive metal layer 9 in the groove 5 lower than that of the surface of the insulating film 3.

Next, as shown in FIG. 5D, the barrier film 7 on the insulating film 3 is removed by the second CMP. The constitution and the forming procedure of the semiconductor device other than this are the same as those of the First Embodiment.

The first CMP of the present embodiment can be carried out, for example, under the following conditions: an abrasive: an abrasive including a silicon dioxide abrasive grain, hydrogen peroxide solution and organic acid (citric acid, etc.); an abrasive flow rate: 200 ml/min; a polishing pressure: 14 kPa; the number of revolutions of a surface plate: 90 rpm; and the number of revolutions of a wafer: 85 rpm. In this time, a polishing rate of the conductive metal layer 9 made of copper becomes 900 nm/min. This CMP is terminated after performing over-polishing for 30 seconds or more after the barrier film 7 is exposed. Thereby, it is possible to make the height of the surface of the conductive metal layer 9 in the groove 5 lower than that of the surface of the insulating film 3.

The second CMP can be carried out, for example, under the following conditions: an abrasive: an abrasive including a silica abrasive grain; an abrasive flow rate: 200 ml/min; a polishing pressure: 21 kPa; the number of revolutions of a surface plate: 100 rpm; and the number of revolutions of a wafer: 93 rpm. In this time, a polishing rate of the conductive metal layer 9 made of copper becomes 100 nm/min, a polishing rate of the barrier film 7 made of tantalum and a tantalum nitride film becomes 100 nm/min, and a polishing rate of the insulating film 3 becomes 10 nm/min or less. This CMP is carried out until the insulating film 3 is exposed.

In this embodiment, in the first CMP, it is preferable to use an abrasive by which a polishing rate of the conductive metal layer 9 is larger (preferably ten times or more) than that of the barrier film 7. In this case, by applying excessive polishing without changing abrasives, it is possible to make the height of the surface of the conductive metal layer 9 in the groove 5 lower than that of the surface of the insulating film 3. Further, as an abrasive for the conductive metal layer 9 made of copper, an abrasive including an oxidizer for copper and an ingredient to etch an oxidized film of copper is preferable.

The above-mentioned conditions of the CMP are not limited to those described above. A method of removing a part of the conductive metal layer 9 is not limited to the CMP and another method may be employed.

### 3. THIRD EMBODIMENT

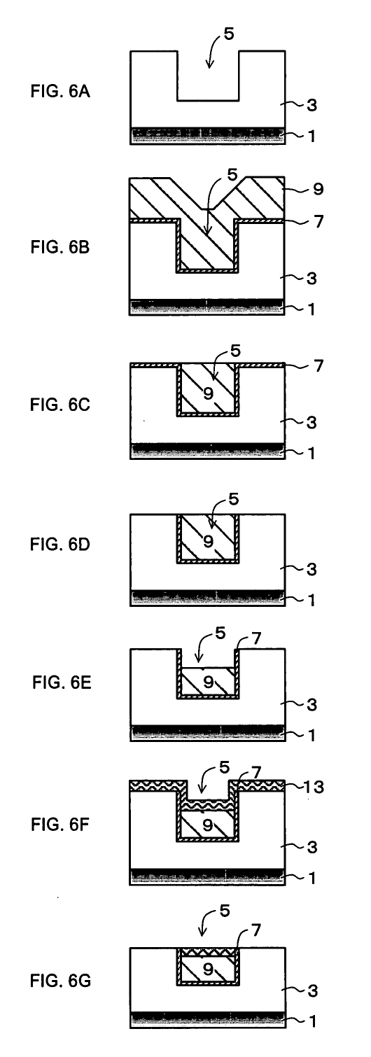

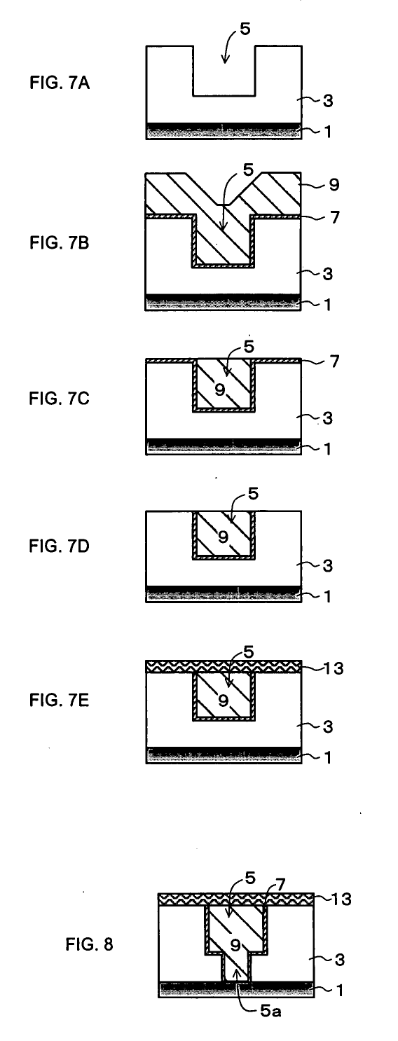

FIGS. 6A to 6G are cross-sectional views for illustrating a method of producing a semiconductor device according to the third embodiment of the present invention. In this embodiment, as shown in FIGS. 6A to 6B, the constitution and the forming procedure of the semiconductor device in the steps up to forming of the conductive metal layer 9 and in the steps from forming of the metal diffusion preventive film 13 shown in FIGS. 6F and 6G on are the same as those of First Embodiment.

As shown in FIG. 6C, the unnecessary conductive metal layer on the barrier film 7 is removed by the first CMP.

Next, as shown in FIG. 6D, the barrier film 7 on the insulating film 3 is removed by the second CMP.

Thereafter, as shown in FIG. 6E, the conductive metal layer 9 in the groove 5 exposed by the second CMP is etched so that the height of the surface of the conductive metal layer 9 becomes lower than that of the surface of the insulating film 3. The constitution and the forming procedure of the semiconductor device other than this are the same as those of First Embodiment.

A type of etching in the present embodiment is not particularly limited, but wet etching is preferable. For the wet etching, common etchants to etch the conductive metal layer 9 are used. When the conductive metal layer 9 is made of copper, common etchants for copper (for example, an etchant made of inorganic acid such as sulfuric acid, hydrochloric acid or phosphoric acid, or made of organic acid such as citric acid, etc., or a mixture prepared by adding hydrogen peroxide solution to the inorganic acid or organic acid) can be used for wet etching. For the conductive metal layer 9 made of copper, the wet etching is carried out, for example, at an etching rate of about 100 nm/min by use of a mixture of sulfuric acid and hydrogen peroxide solution in proportions of 50:1 until a desired film thickness is removed.

In the present embodiment, the first and second CMPs may be carried out by the same method as in conventional embodiments.

In the present embodiment, since the difference in level between the surface of the conductive metal layer 9 in the groove 5 and the surface of the insulating film 3 is formed by an etching process, the control of the difference in level is easier than those in First Embodiment and Second Embodiment. The reason for this is that in First Embodiment and Second Embodiment, the above-mentioned difference in level is affected by a degree of evenness in a wafer surface at the time of depositing or polishing the conductive metal layer 9.

Hereinbefore, the invention made by the present inventor has been specifically described based on the embodiment, but the present invention is not limited to the embodiments described above, and various variations and modifications may be made without departing from the spirit of the invention.

In the above embodiments, examples of configurations based on the single damascene process have been described, but the present invention can be applied to a structure of the dual damascene by forming a groove for interconnection and a hole for connection to a lower layer interconnection as the groove 5.

Various characteristics shown in the above embodiments can be combined with one another. When a plurality of characteristics are included in an embodiment, one or a plurality of characteristics thereof may be appropriately selected from these characteristics, and may be adopted singly or in combination in the present invention.

This application claims priority to Japanese application number 2005-112545, filed on Apr. 8, 2005, which is herein incorporated by reference.

1. A method of producing a semiconductor device comprising the steps of (1) forming a groove in an insulating film formed on a semiconductor substrate, (2) forming a barrier film on the inner surface of the groove and on the insulating film, (3) forming a conductive metal layer on the barrier film so as to fill the groove, (4) removing the conductive metal layer in the groove so that the height of the surface of the conductive metal layer becomes lower than that of the surface of the insulating film, (5) forming a metal diffusion preventive film on the insulating film and on the conductive metal layer, and (6) removing the metal diffusion preventive film on the insulating film and a part of the insulating film so that at least a part of the metal diffusion preventive film on the conductive metal layer remains.

2. The method of claim 1, wherein the step (4) is performed by a CMP method.

3. The method of claim 2, wherein the step (4) comprises the steps of removing the conductive metal layer on the insulating film, and removing the barrier film on the insulating film and a part of the conductive metal layer in the groove.

4. The method of claim 2, wherein the step (4) comprises the steps of removing the conductive metal layer on the insulating film and a part of the conductive metal layer in the groove, and removing the barrier film on the insulating film.

5. The method of claim 1, wherein the step (4) comprises the steps of removing the conductive metal layer and the barrier film on the insulating film by a CMP method, and removing a part of the conductive metal layer in the groove by etching.

6. The method of claim 5, wherein the etching comprises wet etching.

7. The method of claim 1, wherein the step (4) is performed so that the difference in level between the surface of the conductive metal layer and the surface of the insulating film is made 70 nm or more.

8. The method of claim 7, wherein the difference in level is made smaller than the value obtained by subtracting 40 nm from the double value of the film thickness of the metal diffusion preventive film.

9. The method of claim 1, wherein the step (6) is performed so that the insulating film is removed by 50 nm or more.

10. The method of claim 1, wherein the step (6) is performed so that the residual of the metal diffusion preventive film has a thickness of 20 nm or more.

11. A semiconductor device comprising a semiconductor substrate, an insulating film with a groove, formed on the substrate, a conductive metal layer filled into the groove with a barrier film therebetween, and a metal diffusion preventive film formed so as to cover the conductive metal layer, wherein the surface of the insulating film and the surface of the metal diffusion preventive film are substantially in the same plane.
